(19) United States
(12) Patent Application Publication
(10) Pub. No.: US 2026/0152845 A1
(43) Pub. Date: Jun. 4, 2026

(54) SINTERED BODY, SPUTTERING TARGET, OXIDE THIN FILM, THIN FILM TRANSISTOR AND METHOD OF MANUFACTURING SINTERED BODY

(71) Applicant: H & IRUJA CO., LTD., Chungcheongnam-do (KR)

(72) Inventors: HYUNG ROK LEE, Incheon (KR); YU LIN OH, Gyeonggi-do (KR); SUNG KWAN LIM, Seoul (KR); SANG WON SHIN, Gyeonggi-do (KR)

(21) Appl. No.: 19/405,660

(22) Filed: Dec. 2, 2025

(30) Foreign Application Priority Data
Dec. 2, 2024 (KR) 10-2024-0176793

(51) Int. Cl. C23C 14/34; C04B 35/01; C04B 35/64; C23C 14/08; H01J 37/34; H10D 30/67

(52) U.S. Cl. CPC C23C 14/3414; C04B 35/01; C04B 35/64; C23C 14/08; H01J 37/3405; H01J 37/3426; H10D 30/6755; C04B 2235/3284; C04B 2235/3286; C04B 2235/3293; H01J 2237/332

(57) ABSTRACT

A sintered body includes indium (In), tin (Sn), gallium (Ga), zinc (Zn), and oxygen (O). The content of In atoms is 45 to 65 at % based on the total content of the In, Sn, Zn, and Ga atoms, and the content of Ga atoms is greater than 0 at % and 30 at % or less based on the total content of the In, Sn, Zn, and Ga atoms. The sintered body includes In, Sn, Ga, Zn and O and can improve non-uniformity caused by particles, arcing, and the like due to excessive oxygen injection during large-area deposition when forming an oxide thin film using a sputtering target manufactured from the sintered body.

### CROSS-REFERENCE TO RELATED APPLICATION AND CLAIM OF PRIORITY

This application claims the benefit under 35 USC § 119 of Korean Patent Application No. 10-2024-0176793, filed on Dec. 2, 2024 in the Korean Intellectual Property Office, the entire disclosure of which is incorporated herein by reference for all purposes.

### BACKGROUND

### 1. Field of the Invention

The present invention relates to a sintered body, a sputtering target, an oxide thin film, a thin film transistor, and a method of manufacturing a sintered body. More specifically, the present invention relates to a sintered body, a sputtering target, an oxide thin film, a thin film transistor, and a method of manufacturing a sintered body, wherein, when an oxide thin film is formed using a sputtering target manufactured from a sintered body composed of In, Sn, Ga, Zn and O, non-uniformity caused by particles, arcing, and the like due to excessive oxygen injection during large-area deposition can be improved, and a thin film transistor including the deposited oxide thin film exhibits small changes in characteristics depending on the oxygen partial pressure during deposition and has high carrier mobility.

### 2. Description of the Related Art

An amorphous oxide semiconductor exhibits higher carrier mobility than amorphous silicon (a-Si) and can be deposited at low temperatures, making it a suitable material for the active layer of backplanes in next-generation displays that require large-size, high-resolution and high-speed operation.

Conventionally, indium gallium zinc oxide (IGZO) semiconductor targets are mainly used as the backplane active layer in QD/OLED displays. The IGZO oxide semiconductor sputtering process, currently used in mass production of QD/OLED displays, is a critical process that significantly affects panel characteristics and reliability, and is much more sensitive than conventional sputtering processes using metallic materials. To improve panel characteristics and reliability, a high oxygen partial pressure is used during the deposition of an IGZO film, but due to the high oxygen partial pressure, an oxide film is formed on the surface of the ground and target.

The formation of such oxide films decreases conductivity and leads to charging, causing arcing and particle generation. Moreover, changes in plasma potential arising from fluctuations in ground voltage make the quality characteristics of the deposited amorphous thin film highly sensitive to changes in the deposition environment.

For these reasons, controlling the sputtering process is very challenging. In the IGZO sputtering process, periodic pre-sputtering without oxygen gas injection is often conducted to clean the surface of the shield and target. However, pre-sputtering decreases productivity and leads to work losses in the sputtering process. Therefore, there is a need to develop new sputtering targets capable of forming backplane active layers with excellent panel characteristics and reliability even without frequent pre-sputtering.

### SUMMARY

The present invention is directed to providing a sintered body, a sputtering target, and an oxide thin film, wherein non-uniformity caused by particles, arcing, and the like due to excessive oxygen injection during large-area deposition can be improved when an oxide thin film is formed using a sputtering target manufactured from a sintered body composed of In, Sn, Ga, Zn and O.

The present invention is also directed to providing a thin film transistor including the oxide thin film, wherein the thin film transistor exhibits small changes in characteristics depending on the oxygen partial pressure during deposition and has high carrier mobility.

The present invention is also directed to providing a method of manufacturing the sintered body.

According to an aspect of the present invention, there is provided a sintered body including indium (In), tin (Sn), gallium (Ga), zinc (Zn), and oxygen (O), wherein the content of In atoms is 45 to 65 at % based on the total content of the In, Sn, Zn, and Ga atoms, and the content of Ga atoms is greater than 0 at % and 30 at % or less based on the total content of the In, Sn, Zn, and Ga atoms.

The content of Sn atoms may be 5 to 30 at % based on the total content of the Zn and Sn atoms.

According to another aspect of the present invention, there is provided a sputtering target including the sintered body.

The sputtering target may further include a backing plate or a backing tube that is joined to the rear surface of the sintered body to support the sintered body.

The sputtering target may be applied to a DC magnetron sputtering device.

According to still another aspect of the present invention, there is provided an oxide thin film formed using the sputtering target.

According to yet another aspect of the present invention, there is provided a thin film transistor including the oxide thin film.

The thin film transistor may include a channel layer, a source electrode and a drain electrode each connected to the channel layer, and a gate electrode laminated on the channel layer with a gate insulating film interposed therebetween, wherein the channel layer may be the oxide thin film.

According to yet another aspect of the present invention, there is provided a thin film transistor including a channel layer; a gate electrode disposed to overlap the channel layer; and a source electrode and a drain electrode each connected to the channel layer, wherein the channel layer includes indium (In), tin (Sn), gallium (Ga), zinc (Zn), and oxygen (O), the content of In atoms in the channel layer is 45 to 65 at % based on the total content of the In, Sn, Zn, and Ga atoms, and the content of Ga atoms in the channel layer is greater than 0 at % and 30 at % or less based on the total content of the In, Sn, Zn, and Ga atoms.

According to yet another aspect of the present invention, there is provided a method of manufacturing a sintered body including indium (In), tin (Sn), gallium (Ga), zinc (Zn), and oxygen (O), the method including (1) obtaining a powder mixture by mixing In₂O₃ powder, SnO₂ powder, Ga₂O₃ powder, and ZnO powder; and (2) sintering the powder mixture to obtain a sintered body, wherein the powder mixture includes 0.6 to 50 parts by weight of SnO₂ powder, 8 to 50 parts by weight of Ga₂O₃ powder, and 0.3 to 30 parts by weight of ZnO powder, based on 100 parts by weight of In₂O₃ powder.

Prior to sintering in step (2), the method may further include a step of molding the powder mixture by any one process selected from cold pressing, slip casting, filter pressing, cold isostatic pressing, and gel casting.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIGS. 1A to 7 show the switching characteristic measurement results according to the amount of oxygen injected using a sputtering target according to an embodiment of the present invention;

FIG. 8 shows the XRD measurement results of a sputtering target before and after deposition according to an embodiment of the present invention;

FIG. 9 illustrates the switching characteristic measurement device used in the test examples of the present invention; and

FIG. 10 illustrates a thin film transistor according to an embodiment of the present invention.

### DETAILED DESCRIPTION

The following description merely illustrates the principles of the present invention. Therefore, those skilled in the art can implement the principles of the present invention and invent various devices included in the concept and scope of the present invention, although not explicitly described or illustrated herein. In addition, all conditional terms and embodiments listed in this specification are, in principle, explicitly intended solely for the purpose of understanding the concept of the present invention and should be understood as not being limited to such specially enumerated embodiments and states.

Additionally, all detailed descriptions enumerating principles, aspects and embodiments of the present invention as well as specific embodiments should be understood as intended to include structural and functional equivalents thereof. Furthermore, these equivalents should be understood to include not only currently known equivalents but also equivalents to be developed in the future, that is, all elements invented to perform the same function regardless of structure.

The above objects, features and advantages will become more apparent through the following detailed description in conjunction with the attached drawings, and accordingly, those having ordinary skill in the technical field to which the present invention pertains will be able to readily implement the technical idea of the present invention. Furthermore, in describing the present invention, if it is determined that a detailed explanation of known technology related to the present invention may unnecessarily obscure the gist of the present invention, such detailed explanations will be omitted.

Hereinafter, the sintered body of the present invention will be described in detail.

The sintered body of the present invention is for manufacturing a sputtering target used in the sputtering process to deposit the active layer of a thin film transistor. Sputtering is a method of colliding plasma particles with a target at high speed and depositing particles ejected from the target onto a substrate positioned opposite the target.

According to an embodiment of the present invention, the sintered body includes indium (In), tin (Sn), gallium (Ga), zinc (Zn), and oxygen (O), wherein the content of In atoms may be 45 to 65 at % based on the total content of the In, Sn, Zn, and Ga atoms, and the content of Ga atoms may be greater than 0 at % and 30 at % or less based on the total content of the In, Sn, Zn, and Ga atoms.

The content of Sn atoms may be 5 to 30 at % based on the total content of the Zn and Sn atoms.

A sputtering target may be manufactured using the sintered body.

The sputtering target may further include a backing plate or a backing tube that is joined to the rear surface of the sintered body and supports the sintered body. The backing plate or backing tube serves to support one or a plurality of sintered bodies. To this end, the backing plate or backing tube is disposed behind the sintered body and bonded via a bonding material. The backing plate or backing tube has excellent electrical conductivity and thermal conductivity, and may be made of oxygen-free copper, titanium, and the like, which have low thermal deformation.

The sputtering target may be applied to a DC magnetron sputtering device. Since DC magnetron sputtering devices are generally used for large-area oxide thin film deposition, the sintered body constituting the target may be processed into a divided form, such as a tile or a cylindrical tube.

The oxide thin film deposited by the sputtering target may be used as the active layer (channel layer) of a thin film transistor, and the thin film transistor exhibits stable switching characteristics regardless of the amount of oxygen gas introduced into the argon gas in the sputtering process.

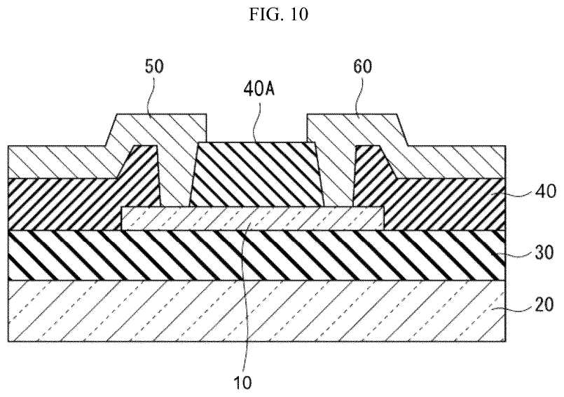

The thin film transistor will be described in more detail with reference to FIG. 10.

The thin film transistor includes an oxide thin film 10, a silicon wafer 20, a gate insulating film 30, interlayer insulating films 40 and 40A, a source electrode 50, and a drain electrode 60.

The silicon wafer 20 is a gate electrode. The gate insulating film 30 is an insulating film that blocks electrical conduction between the gate electrode and the oxide thin film 10 and is formed on the silicon wafer 20.

The oxide thin film 10 is a channel layer and is formed on the gate insulating film 30.

The source electrode 50 and the drain electrode 60 are conductive terminals for supplying source current and drain current to the oxide thin film 10, respectively, and are formed to contact regions near both ends of the oxide thin film 10.

The interlayer insulating film 40 is an insulating film that blocks electrical conduction except at the contact portions between the source electrode 50, the drain electrode 60, and the oxide film 10.

The interlayer insulating film 40A is an insulating film that blocks electrical conduction except at the contact portions between the source electrode 50, the drain electrode 60, and the oxide film 10. The interlayer insulating film 40A also blocks electrical conduction between the source electrode 50 and the drain electrode 60. Additionally, the interlayer insulating film 40A serves as a protective layer for the channel layer.

There are no particular limitations on the materials forming the drain electrode 60, the source electrode 50, and gate electrode, and commonly used materials may be arbitrarily selected. As an example, a silicon wafer may be used as a substrate, and although silicon wafers also act as electrodes, the electrode material is not limited to silicon.

For example, transparent electrodes such as indium tin oxide (ITO), indium zinc oxide (IZO), ZnO, and SnO₂, metal electrodes such as Al, Ag, Cu, Cr, Ni, Mo, Au, Ti, and Ta, or metal electrodes or laminated electrodes of alloys containing them may be used. A gate electrode may be formed on a substrate such as glass.

There are no particular limitations on the materials forming the interlayer insulating films 40 and 40A, and commonly used materials may be arbitrarily selected. Specifically, as materials for forming the interlayer insulating films 40 and 40A, compounds such as SiO₂, SiNₓ, Al₂O₃, Ta₂O₅, TiO₂, MgO, ZrO₂, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, and AlN may be used.

Hereinafter, a method of manufacturing the sintered body of the present invention will be described.

The sintered body of the present invention may be manufactured by powder metallurgy.

First, In₂O₃ powder, SnO₂ powder, Ga₂O₃ powder, and ZnO powder are mixed to obtain a powder mixture (Step 1).

The powder mixture includes 0.6 to 50 parts by weight of SnO₂ powder, 8 to 50 parts by weight of Ga₂O₃ powder, and 0.3 to 30 parts by weight of ZnO powder, based on 100 parts by weight of In₂O₃ powder.

Next, the powder mixture is sintered to obtain a sintered body (Step 2).

Prior to sintering, the method may further include a molding step using molding methods such as cold pressing, slip casting, filter pressing, cold isostatic pressing, and gel casting.

Preferably, the powder mixture may be maintained at a temperature range of 1400 to 1550° C. for 10 hours or more using pressureless sintering to manufacture a sintered body with a relative density of 95% or more.

The sintered body may be bonded to the backing plate or the backing tube via a bonding material to manufacture a sputtering target.

An oxide thin film may be formed by a sputtering process using the sputtering target, and at this time, the heat treatment process of the oxide thin film at 400° C. or below may be further included, and the oxide thin film may be used as a channel layer of the thin film transistor.

The thin film transistor, including the oxide thin film, exhibits high carrier mobility and reliability, and shows small changes in characteristics depending on the oxygen partial pressure during the oxide thin film deposition process.

### Example

Hereinafter, the present invention will be described with reference to preferred examples. However, these examples are for illustrative purposes and do not limit the scope of the present invention.

### Example: Manufacture of Sintered Body

In₂O₃ powder, SnO₂ powder, Ga₂O₃ powder, and ZnO powder were mixed to prepare a powder mixture, and the powder mixture was sintered to obtain a sintered body having the composition shown in Table 1 below.

TABLE 1

| | Composition (at %) | | | | Atomic ratio 1 | Atomic ratio 2 | Atomic ratio 3 |
|---|---|---|---|---|---|---|---|
| Sample No. | Ga | In | Sn | Zn | Ga/(In + Ga + Zn + Sn) | In/(In + Ga + Zn + Sn) | Sn/(Zn + Sn) |
| 1 | 10 | 81 | 0.9 | 8.1 | 10 | 81 | 10 |
| 2 | 10 | 81 | 2.7 | 6.3 | 10 | 81 | 30 |
| 3 | 10 | 81 | 4.5 | 4.5 | 10 | 81 | 50 |
| 4 | 10 | 81 | 6.3 | 2.7 | 10 | 81 | 70 |
| 5 | 10 | 81 | 8.1 | 0.9 | 10 | 81 | 90 |
| 6 | 10 | 72 | 1.8 | 16.2 | 10 | 72 | 10 |
| 7 | 10 | 72 | 5.4 | 12.6 | 10 | 72 | 30 |
| 8 | 10 | 72 | 9 | 9 | 10 | 72 | 50 |
| 9 | 10 | 72 | 12.6 | 5.4 | 10 | 72 | 70 |
| 10 | 10 | 72 | 16.2 | 1.8 | 10 | 72 | 90 |
| 11 | 10 | 63 | 2.7 | 24.3 | 10 | 63 | 10 |
| 12 | 10 | 63 | 8.1 | 18.9 | 10 | 63 | 30 |
| 13 | 10 | 63 | 13.5 | 13.5 | 10 | 63 | 50 |
| 14 | 10 | 63 | 18.9 | 8.1 | 10 | 63 | 70 |
| 15 | 10 | 63 | 24.3 | 2.7 | 10 | 63 | 90 |
| 16 | 10 | 54 | 3.6 | 32.4 | 10 | 54 | 10 |
| 17 | 10 | 54 | 10.8 | 25.2 | 10 | 54 | 30 |
| 18 | 10 | 54 | 18 | 18 | 10 | 54 | 50 |
| 19 | 10 | 54 | 25.2 | 10.8 | 10 | 54 | 70 |
| 20 | 10 | 54 | 32.4 | 3.6 | 10 | 54 | 90 |
| 21 | 10 | 45 | 4.5 | 40.5 | 10 | 45 | 10 |
| 22 | 10 | 45 | 13.5 | 31.5 | 10 | 45 | 30 |
| 23 | 10 | 45 | 22.5 | 22.5 | 10 | 45 | 50 |
| 24 | 10 | 45 | 31.5 | 13.5 | 10 | 45 | 70 |
| 25 | 10 | 45 | 40.5 | 4.5 | 10 | 45 | 90 |
| 26 | 20 | 72 | 0.8 | 7.2 | 20 | 72 | 10 |
| 27 | 20 | 72 | 2.4 | 5.6 | 20 | 72 | 30 |
| 28 | 20 | 72 | 4 | 4 | 20 | 72 | 50 |
| 29 | 20 | 72 | 5.6 | 2.4 | 20 | 72 | 70 |
| 30 | 20 | 72 | 7.2 | 0.8 | 20 | 72 | 90 |
| 31 | 20 | 64 | 1.6 | 14.4 | 20 | 64 | 10 |
| 32 | 20 | 64 | 4.8 | 11.2 | 20 | 64 | 30 |
| 33 | 20 | 64 | 8 | 8 | 20 | 64 | 50 |
| 34 | 20 | 64 | 11.2 | 4.8 | 20 | 64 | 70 |
| 35 | 20 | 64 | 14.4 | 1.6 | 20 | 64 | 90 |
| 36 | 20 | 56 | 2.4 | 21.6 | 20 | 56 | 10 |
| 37 | 30 | 63 | 0.7 | 6.3 | 30 | 63 | 10 |
| 38 | 30 | 63 | 2.1 | 4.9 | 30 | 63 | 30 |
| 39 | 30 | 63 | 3.5 | 3.5 | 30 | 63 | 50 |
| 40 | 30 | 63 | 4.9 | 2.1 | 30 | 63 | 70 |
| 41 | 30 | 63 | 6.3 | 0.7 | 30 | 63 | 90 |
| 42 | 30 | 56 | 1.4 | 12.6 | 30 | 56 | 10 |
| 43 | 30 | 56 | 4.2 | 9.8 | 30 | 56 | 30 |
| 44 | 30 | 56 | 7 | 7 | 30 | 56 | 50 |
| 45 | 30 | 56 | 9.8 | 4.2 | 30 | 56 | 70 |
| 46 | 30 | 56 | 12.6 | 1.4 | 30 | 56 | 90 |
| 47 | 40 | 54 | 0.6 | 5.4 | 40 | 54 | 10 |
| 48 | 40 | 54 | 1.8 | 4.2 | 40 | 54 | 30 |
| 49 | 40 | 54 | 3 | 3 | 40 | 54 | 50 |
| 50 | 40 | 54 | 4.2 | 1.8 | 40 | 54 | 70 |
| 51 | 40 | 54 | 5.4 | 0.6 | 40 | 54 | 90 |

### TEST EXAMPLES

### Test Example 1: Switching Characteristic Measurement

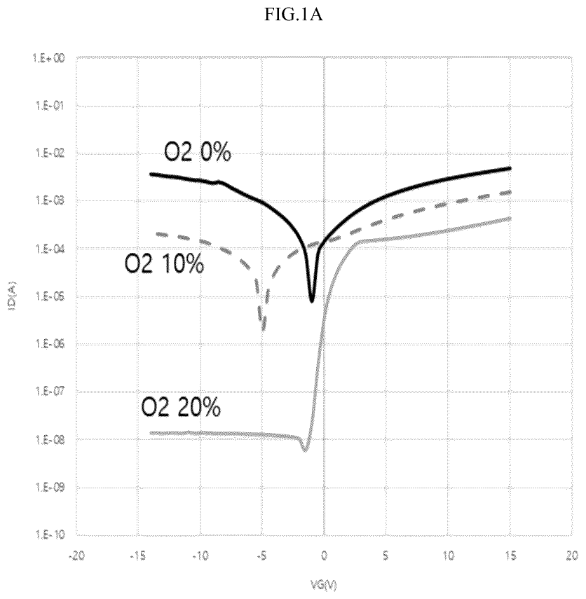

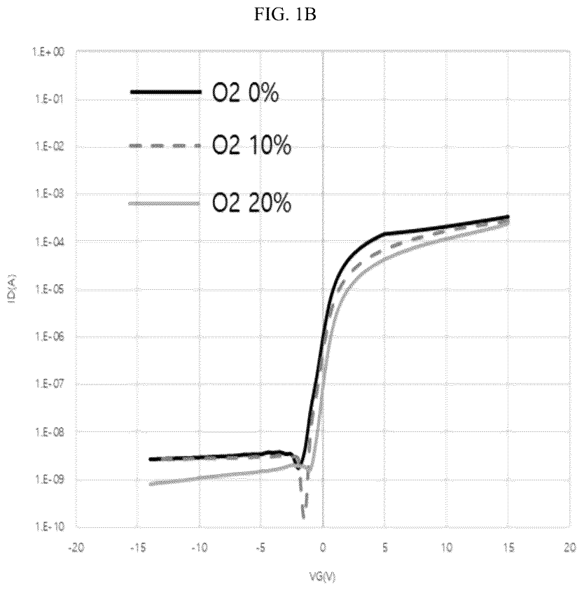

A sputtering target was manufactured from the sintered body manufactured according to the example, the target was mounted on a DC magnetron sputtering device, and an oxide semiconductor film (active layer) was deposited on a wafer. The sputtering was carried out at room temperature under an atmosphere of a mixed gas including argon and a predetermined amount of oxygen gas, and the film was deposited to a thickness of approximately 400 Å. The switching characteristics of the deposited oxide semiconductor film (active layer) according to the amount of input oxygen gas were measured, and the results are shown in FIGS. 1A to 7.

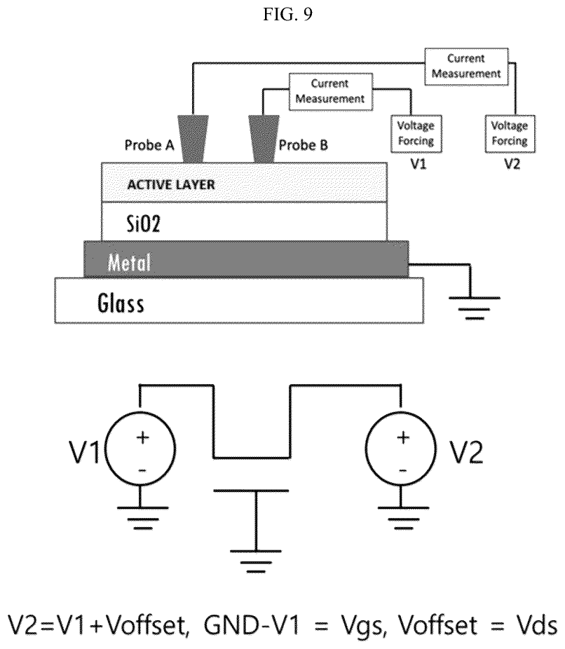

FIG. 9 shows the device used to measure the switching characteristics. Electrical signals are applied by contacting at least two points on one surface of the oxide semiconductor film (IGZO), thereby detecting the electrical characteristics of the oxide semiconductor film. Different voltages are applied to Probe A and Probe B through voltage sources V1 and V2, respectively. The voltage difference between V1 and V2 becomes the voltage applied to the oxide semiconductor film (Vds), while the voltage between V1 and ground (GND) becomes the gate voltage (Vgs). The current flowing through the oxide semiconductor film according to the applied voltage is measured with an ammeter. By analyzing the measured current-voltage (I-V) characteristics, the switching characteristics of the oxide semiconductor film may be understood.

FIGS. 1A and 1B show the switching characteristics measured according to the amount of input oxygen for sample No. 1 (FIG. 1A) and sample No. 22 (FIG. 1B). Sample No. 1 had a very high In atomic ratio of 81, relative to the sum of In, Sn, Zn, and Ga atoms. This resulted in very large variations in the switching characteristics of the active layer. In contrast, sample No. 22 had an In atomic ratio of 45, a Ga atomic ratio of 10, each relative to the sum of In, Sn, Zn, and Ga atoms, and had an Sn atomic ratio of 30, relative to the sum of Zn and Sn atoms. This resulted in very small variations in the switching characteristics of the active layer.

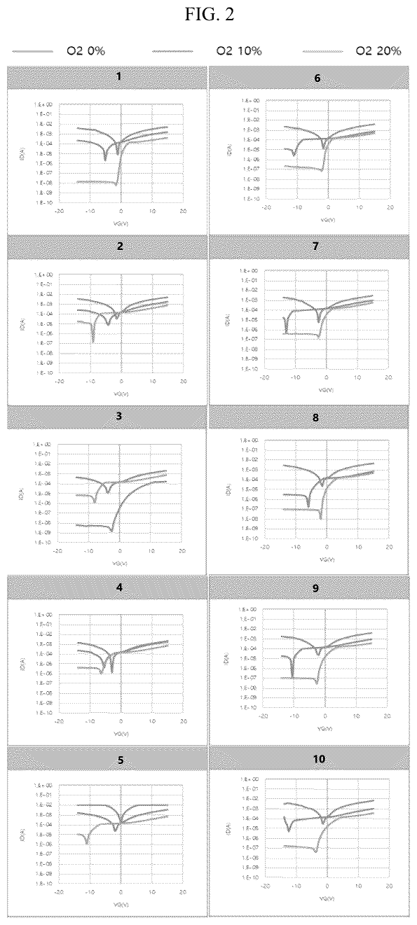

Referring to sample Nos. 1 to 10 in FIG. 2, all samples had atomic ratio 2 values ranging from 72 to 81, indicating high In content, which resulted in very large variations in the switching characteristics of the active layer. In addition, no switching performance of the thin film was observed when oxygen was not introduced.

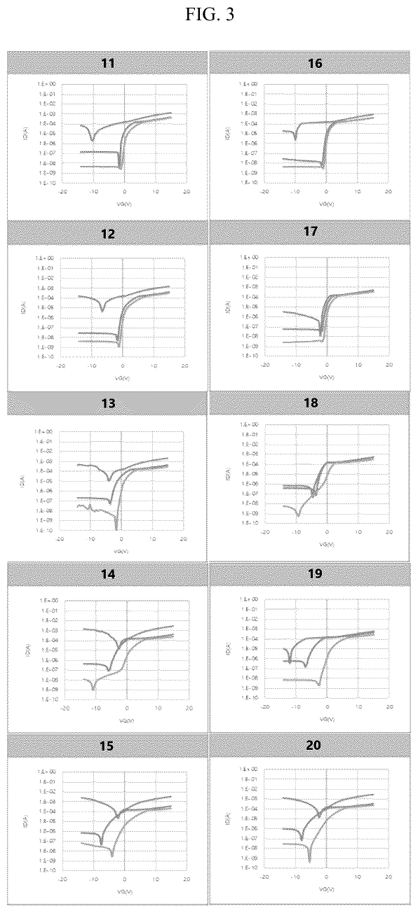

Referring to sample Nos. 11 to 20 in FIG. 3, when the Sn content was high (atomic ratio 3 ranging from 50 to 90), the switching characteristics decreased. In contrast, when the Sn content was low (sample Nos. 11, 12, 16, and 17), the switching characteristics did not decrease and the variation in characteristics was small.

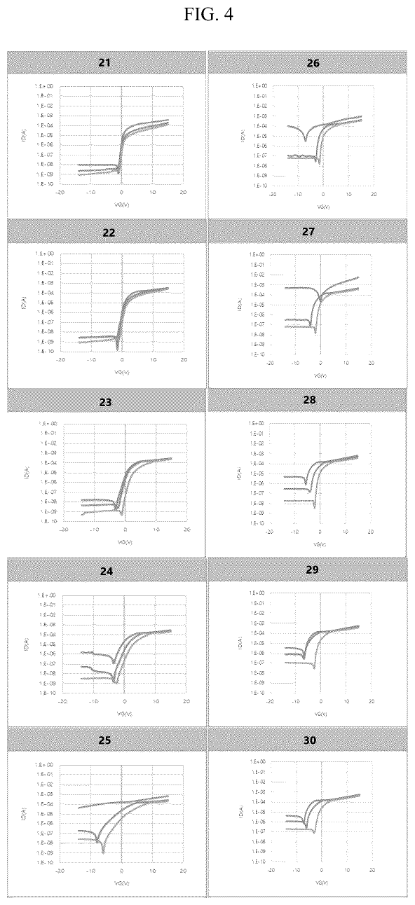

Referring to sample Nos. 21 to 31 in FIG. 4, when the In content was low but the Sn content was high (sample Nos. 23 to 25), the switching characteristics decreased. When the In content was high (sample Nos. 26 to 30), no switching performance was observed when oxygen was not introduced, regardless of the Sn content. In contrast, when both In and Sn contents were low (sample Nos. 26 and 27), the variation in characteristics was small, which was preferable.

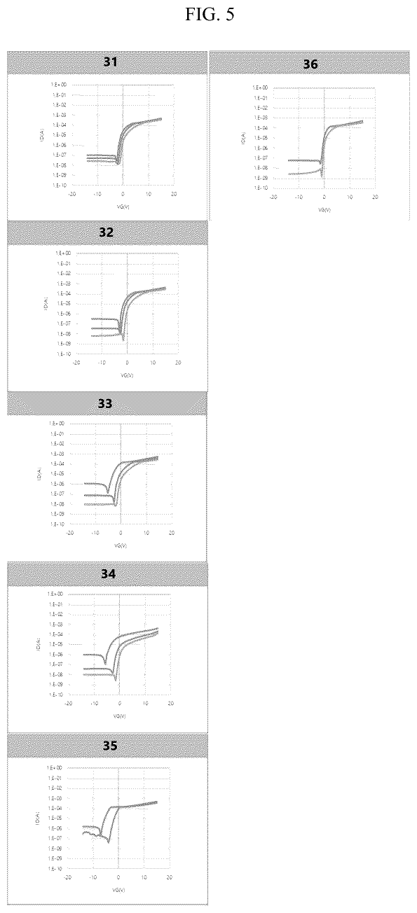

Referring to sample Nos. 31 to 36 in FIG. 5, when the Sn content was high (sample Nos. 33 to 35), the switching characteristics decreased. When the Sn content was low (sample Nos. 31, 32, and 36), the variation in characteristics was small, which was preferable.

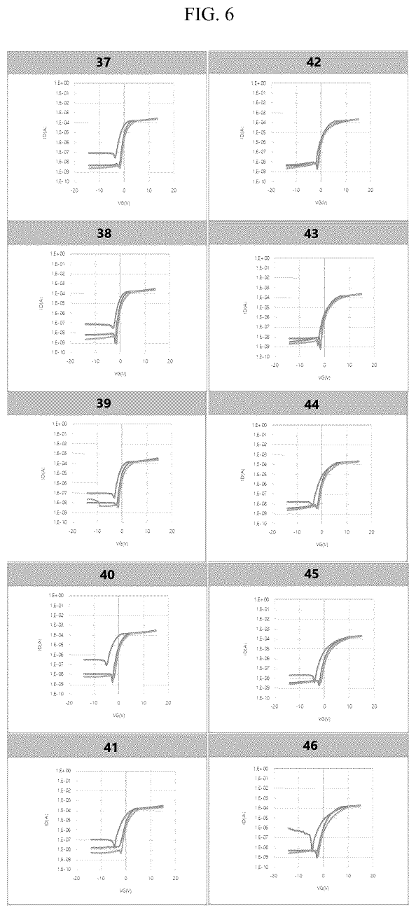

Referring to sample Nos. 37 to 46 in FIG. 6, when the Sn content was high (sample Nos. 39 to 41 and 44 to 46), the switching characteristics decreased. When the Sn content was low (sample Nos. 37, 38, 42, and 43), the variation in characteristics was small, which was preferable.

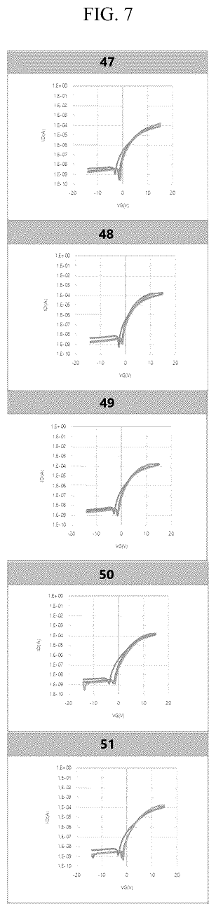

Referring to sample Nos. 47 to 51 in FIG. 7, when the Ga content was high, switching characteristics were observed, but the on/off switching speed performance of the thin film transistor (TFT) was degraded.

In summary, in regions where the In content was high relative to the sum of In, Sn, Zn, and Ga atoms, no switching performance of the thin film was observed when oxygen was not introduced. In addition, in regions where the Ga content was high relative to the sum of In, Sn, Zn, and Ga atoms, switching characteristics appeared but the on/off switching speed was reduced. The higher the Sn content relative to the sum of Sn and Zn atoms, the more the switching characteristics were degraded.

Therefore, the most desirable performance was achieved when the In content was 45 to 65 at % and the Ga content was greater than 0 and 30 at % or less, both relative to the sum of In, Sn, Zn, and Ga atoms, and the Sn content was 5 to 30 at %, relative to the sum content of Zn and Sn atoms.

### Test Example 2: XRD Measurement

A target was manufactured from the sintered body of sample No. 22, and the target was mounted on a DC magnetron sputtering device to deposit an oxide semiconductor film (active layer) on a wafer. The sputtering was carried out at room temperature under an atmosphere of a mixed gas composed of argon and 10% oxygen, and the film was deposited to a thickness of approximately 400 Å.

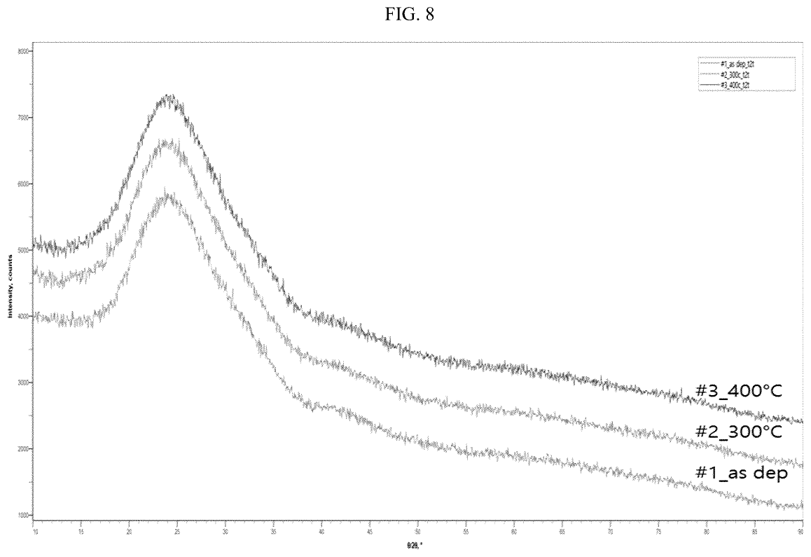

FIG. 8 shows the XRD measurement results immediately after deposition (#1_as dep), after heat treatment at 300° C. after deposition (#2_300° C.), and after heat treatment at 400° C. after deposition (#2_400° C.).

Referring to FIG. 8, no crystalline peaks appeared before and after heat treatment. Therefore, it was confirmed that the amorphous oxide semiconductor film (active layer) was successfully deposited.

The sintered body according to embodiments of the present invention includes In, Sn, Ga, Zn and O, and when an oxide thin film is formed using a sputtering target manufactured from the sintered body, non-uniformity caused by particles, arcing, and the like due to excessive oxygen injection during large-area deposition can be improved.

Additionally, since the thin film transistor of the present invention includes the oxide thin film, it can exhibit small changes in characteristics depending on the oxygen partial pressure during deposition, as well as high carrier mobility.

In addition, the present invention can provide a method of manufacturing the sintered body including In, Sn, Ga, Zn, and O.

However, the effects of the present invention are not limited to the above effects and can be variously expanded within the scope that does not depart from the spirit and scope of the present invention.

Although the present invention has been described with reference to the examples, those skilled in the art will understand that the present invention can be variously modified and changed within a scope that does not depart from the spirit and scope of the present invention as described in the following claims.

What is claimed is:

1. A sintered body comprising:
indium (In);
tin (Sn);
gallium (Ga);
zinc (Zn); and
oxygen (O),
wherein the content of In atoms is 45 to 65 at % based on the total content of the In, Sn, Zn, and Ga atoms, and
the content of Ga atoms is 10 to 30 at % based on the total content of the In, Sn, Zn, and Ga atoms.

2. The sintered body of claim 1, wherein the content of Sn atoms is 5 to 30 at % based on the total content of the Zn and Sn atoms.

3. A sputtering target comprising the sintered body of claim 1.

4. The sputtering target of claim 3, further comprising a backing plate or a backing tube joined to a rear surface of the sintered body to support the sintered body.

5. The sputtering target of claim 3, wherein the sputtering target is applied to a DC magnetron sputtering device.

6. An oxide thin film formed using the sputtering target of claim 3.

7. A thin film transistor comprising the oxide thin film of claim 6.

8. The thin film transistor of claim 7, comprising:
a channel layer;
a source electrode and a drain electrode each connected to the channel layer; and
a gate electrode laminated on the channel layer with a gate insulating film interposed therebetween,
wherein the channel layer is the oxide thin film.

9. A thin film transistor comprising:
a channel layer;
a gate electrode disposed to overlap the channel layer; and
a source electrode and a drain electrode each connected to the channel layer,
wherein the channel layer includes indium (In), tin (Sn), gallium (Ga), zinc (Zn), and oxygen (O),
the content of In atoms in the channel layer is 45 to 65 at % based on the total content of the In, Sn, Zn, and Ga atoms, and
the content of Ga atoms in the channel layer is 10 to 30 at % based on the total content of the In, Sn, Zn, and Ga atoms.

10. A method of manufacturing a sintered body including indium (In), tin (Sn), gallium (Ga), zinc (Zn), and oxygen (O), the method comprising:
obtaining a powder mixture by mixing In₂O₃ powder, SnO₂ powder, Ga₂O₃ powder, and ZnO powder; and
sintering the powder mixture to obtain a sintered body,
wherein, in the sintered body, the content of In atoms is 45 to 65 at % based on the total content of the In, Sn, Zn, and Ga atoms; and
the content of Ga atoms is 10 to 30 at % based on the total content of the In, Sn, Zn, and Ga atoms.

11. The method of claim 10, further comprising, prior to the sintering, molding the powder mixture by any one process selected from the group consisting of cold pressing, slip casting, filter pressing, cold isostatic pressing, and gel casting.
